(19) United States
(12) Patent Application Publication
(10) Pub. No.: US 2006/0102948 A1
(43) Pub. Date: May 18, 2006

(54) METHOD OF FABRICATING FLASH MEMORY

(76) Inventors: Ko-Hsing Chang, Hsinchu (TW); Su-Yuan Chang, Hsinchu Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/160,326

(22) Filed: Jun. 20, 2005

(30) Foreign Application Priority Data
Nov. 15, 2004 (TW) 93134870

(51) Int. Cl. H01L 29/788

(52) U.S. Cl. 257/315

(57) ABSTRACT

A method of fabricating a flash memory is provided. The method includes forming a mask layer with first openings on the substrate. A tunneling dielectric layer is formed at bottom in the first openings. Strips of conductive spacers are formed on sidewalls of the first openings, and source/drain regions are formed in the substrate within the first openings. The strips of conductive spacers are patterned to form floating gates. A first inter-gate dielectric layer is formed over the substrate. Control gates are formed on the substrate to fill the first openings. Mask layer is removed to form second openings. Gate dielectric layer is formed at bottom of second openings, and second inter-gate dielectric layer is formed on the sidewalls of floating gates, and the sidewalls and top surface of the control gates. Word lines are formed to fill second openings disposed between the floating gates and cover the control gates.

### CROSS-REFERENCE TO RELATED APPLICATION

This application claims the priority benefit of Taiwan application serial no. 93134870, filed on Nov. 15, 2004. All disclosure of the Taiwan application is incorporated herein by reference.

### BACKGROUND OF THE INVENTION

1. Field of Invention

The present invention relates to a method of fabricating a semiconductor device. More particularly, the present invention relates to a method for fabricating a flash memory.

2. Description of Related Art

As the microprocessor of the computer becomes more powerful and the programming of the software becomes more complex, the demands for large-capacity memory devices keep increasing. The current trend of memory fabrication process for an integrated circuit is to increase the storage density and the data storage amount in the memory device. In order to fabricate cheap and large-capacity memories, the dimension of the memories keeps shrinking and the integration of the memories becomes higher.

According to different functions, memories can generally be divided as volatile memories and non-volatile memories. The flash memory device allows multiple and repetitive writing, reading and erasure operations, and the storage data are retained even after the power supply is discontinued. Because of the aforementioned advantages, the flash memory has become the mainstream non-volatile memory device, which is widely applied in the electronic products and personal computers.

In general, the flash memory cell includes a stacked gate, made of doped polysilicon and consisting of a floating gate and a control gate. A dielectric layer is disposed between the floating gate and the control gate, while a tunneling oxide layer is located between the floating gate and the substrate. During operations of writing/erasure for the flash memory, bias voltages are applied to the control gate and the source/drain region so that electrons are injected to or extracted from the floating gate. When reading the information stored in the flash memory, a working voltage is applied to the control gate. The charged status of the control gate will affect the on/off state of the underlying channel, while the on/off state of the channel will be considered as “0” or “1” for the read data.

However, when the semiconductor fabricating technology achieves the deep sub-micron, the device size is gradually reduced. With respect to memory device, it means that the size of memory cell is gradually reduced. On the other hand, as the necessary processing or information storage for the information electronic products, such as computer, mobile phone, digital camera, or personal digital assistant (PDA), is increasing. For this situation about requiring the reduced size and increasing memory capacity, it is the goal for the manufacturers to consider the reduced size, high integration, and the memory quality together at the same time.

At present, double gate flash memories have been proposed as disclosed in U.S. Pat. No. 6,344,993. As shown in FIG. 1, a plurality of floating gates 102a and a plurality of floating gates 102b are disposed on the substrate 100, and located above the channel region 106 between the source/drain regions 104a, 104b. A select gate (word line 108) is disposed between the floating gates 102a, 102b. Control gates 110a, 110b are respectively disposed above the floating gates 102a, 102b. The extension direction of the control gates 110a, 110b is vertical to the word line 108, while two adjacent memory cells share one control gate.

However, during the fabrication of the double gate flash memory, the floating gates 102a, 102b are defined and patterned by photolithography and etching. Due to many uncontrollable factors of photolithography, misalignment often occurs to the floating gates during the photolithography process, and the fabricating process is more complicate. On the other hand, under the trend to increase the device integration, the device size is reduced in accordance with the design rule. In general, if the gate couple ratio (GCR) between the floating gate and the control gate is larger, the required operation voltage can be lower, thus increasing the efficiency of the device. In order to increase the gate couple ratio, either the capacitance of the inter-gate dielectric layer is increased or the capacitance of the tunneling oxide layer is decreased. For increasing the capacitance of the inter-gate dielectric layer, it is necessary to increase the overlapped area of the control gate and the floating gate. However, as the integration of the device becomes higher and the size of the device is minimized based on the design rule, it is difficult to increase the overlapped area of the control gate and the floating gate, and it therefore has the issues for incapable of increasing the GCR between the floating gate and the control gate, and increasing the device integration.

### SUMMARY OF THE INVENTION

The invention provides a method for fabricating a flash memory by forming the floating gate and the control gate in a self-aligned way, thus simplifying the fabrication processes. The method of the present invention can also increase the gate couple ratio between the floating gate and the control gate and improve the yield of the products.

As embodied and broadly described herein, the fabrication method of the present invention is provided for forming a flash memory. The fabrication method includes: providing a substrate; forming a mask layer on the substrate; patterning the mask layer to form a plurality of first trenches; forming a tunneling dielectric layer on a bottom surface of the first trenches; forming plural strips of conductive spacers on sidewalls of the first trenches; forming a plurality of source/drain regions in the substrate within the first trenches, using the conductive spacers as masks; patterning the strips of conductive spacers to form a plurality of floating gates; forming a first inter-gate dielectric layer over the substrate; forming a plurality of control gates that fill up the first trenches; removing the mask layer to form a plurality of second trenches; forming a gate dielectric layer on a bottom surface of the second trenches and forming a second inter-gate dielectric layer covering the floating gate and the control gate; and forming a plurality of word lines over the floating gates, wherein the word lines fill up the second trenches between the floating gates and an extension direction of the word line intersects with that of the source/drain region.

In the present invention, the method for forming plural strips of conductive spacers on sidewalls of the first trenches includes forming a first conductive layer over the substrate, and by the self-align process, the anisotropic etching process is used to remove a portion of the first conductive layer, so as to form the strips of conductive spacers on the sidewalls of the first trenches.

In the present invention, the method for forming the control gates that fill up the first trenches includes forming a second conductive layer over the substrate, and removing a portion of the second conductive layer other than the first trenches, so as to form the control gate.

In the present invention, the method for removing the portion of the second conductive layer other than the first trenches includes anisotropic etching process or chemical mechanical polishing.

In the present invention, a material for forming the first inter-gate dielectric layer includes silicon oxide/silicon nitride/silicon oxide. A material for forming the second inter-gate dielectric layer includes silicon oxide. A material for forming the gate dielectric layer includes silicon oxide.

In the present invention, the method for forming the gate dielectric layer on the bottom surface of the second trenches and forming the second inter-gate dielectric layer covering the floating gate and the control gate include thermal oxidation.

In the present invention, a material for the floating gate, the control gate include doped polysilicon. A material for the mask layer has different etching selectivity from the material for the floating gate and the control gate. The material for the mask layer can be silicon nitride.

In the present invention, before forming the mask layer over the substrate, the method further includes forming a lining layer on the substrate. The method for forming the lining layer includes thermal oxidation. In addition, after forming the patterned mask layer, the method further includes removing a portion of the lining layer exposed by the firs trenches.

In the present invention, since the self-align is taken during forming the floating gate without using the photolithographic process, the fabrication condition is loose, and fabrication cost and time can be saved.

In addition, after the first conductive layer is formed over the substrate to fill the first trenches, the control gate is formed by chemical mechanical polishing or etching back processes to remove the portion of the conductive layer other than the trenches. Similarly, during the processes for forming the control gate, the photolithographic process is not used, then the fabrication condition is loose, and fabrication cost and time can be saved.

In addition, according to the method of the present invention fot fabricating the floating gate, the top with a side forms a smooth curve. Therefore, the flash memory of the present invention, in comparing with the flash memory with the conventional stacked gate, the floating gate and the control gate can have large overlapping area, so that the GCR between the floating gate and the control gate can be improved, and therefore the device operation speed and performance can be improved.

In addition, since the top of the floating gate adjacent to the word line has a sharp corner, a stronger electric filed at the corner of the floating gate can be produced during erasing the data. As a result, electrons can fast flow to the word line through the location at sharp corner. The erase time can be reduced.

Accordingly, the present invention provides a flash memory structure, including: a substrate; a plurality of buried bit-lines, a plurality of select gate, a plurality of floating gate, a plurality of control gates, a plurality of first inter-gate dielectric layers, a plurality of second inter-gate dielectric layers, a plurality of gate dielectric layers, and a plurality of tunneling dielectric layers. The bit-lines are disposed in the substrate, arranged parallel to each other and extended in a first direction. The plurality of word lines are disposed over the substrate, arranged parallel to each other and extended in a second direction, wherein the first direction is crossing the second direction. The plurality of select gates are disposed below the word lines and between the buried bit-lines with a distance. The plurality of floating gates are disposed respectively on sidewalls of the select gates, wherein the other sides of the floating gates are adjacent to the buried bit-lines and top portions of the floating gates have sharp corners that are lower than a top surface of the select gates. The plurality of control gates are disposed above the buried bit-lines and between two adjacent floating gates. The plurality of first inter-gate dielectric layers are disposed between the control gates and the floating gates and between the control gates and the buried bit-lines. The plurality of second inter-gate dielectric layers are disposed between the word lines and the control gates and between the floating gates and the select gates. The plurality of gate dielectric layers are disposed between the select gates and the substrate. The plurality of tunneling dielectric layers are disposed between the floating gates and the substrate.

For the flash memory structure of this invention, because the floating gate has a smooth-curved shape, the overlapped area between the floating gate and the control gate becomes larger and the gate couple ratio between the floating gate and the control gate is increased, thus increasing the operation speed and enhancing the performance of the memory structure.

In addition, since the top of the floating gate adjacent to the word line has a sharp corner, a stronger electric filed at the sharp corner of the floating gate can be produced during erasing the data. As a result, electrons can fast flow to the select gate (word line) through the location at sharp corner. The erase time can be reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a top view illustrating a prior art double gate flash memory.

FIGS. 2A-2E are top views illustrating the process steps for forming a flash memory structure according to one preferred embodiment of the present invention.

FIGS. 3A-3E are cross-sectional views illustrating the process steps for forming the flash memory structure of FIGS. 2A-2e along the line A-A′, according to one preferred embodiment of the present invention.

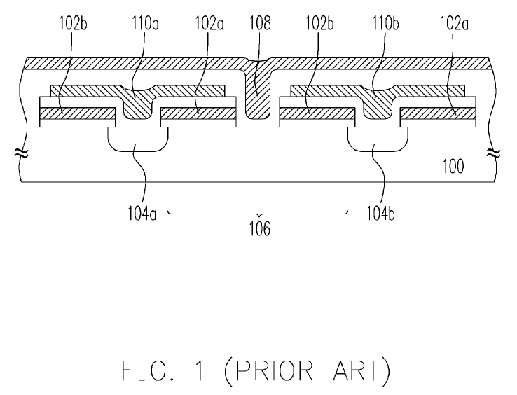

### DESCRIPTION OF THE PREFERRED EMBODIMENTS

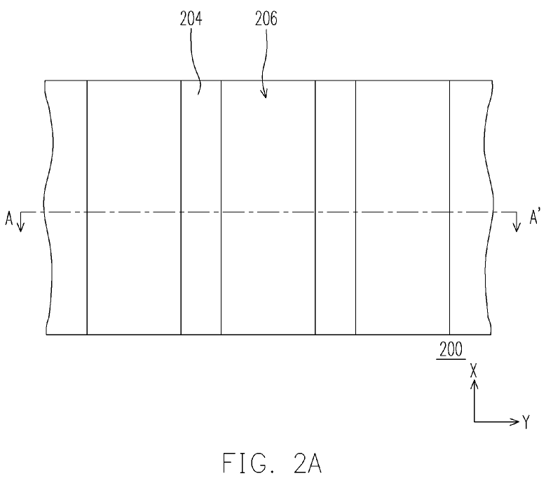

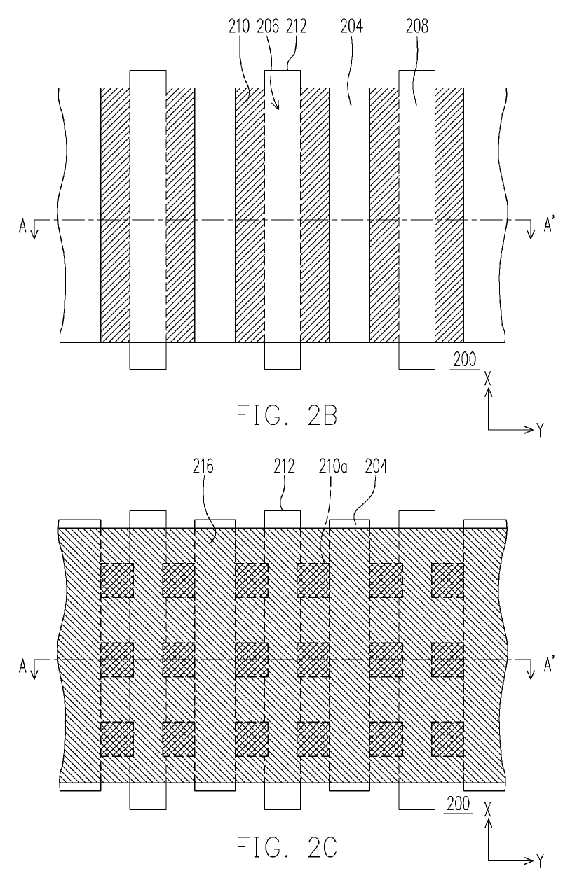

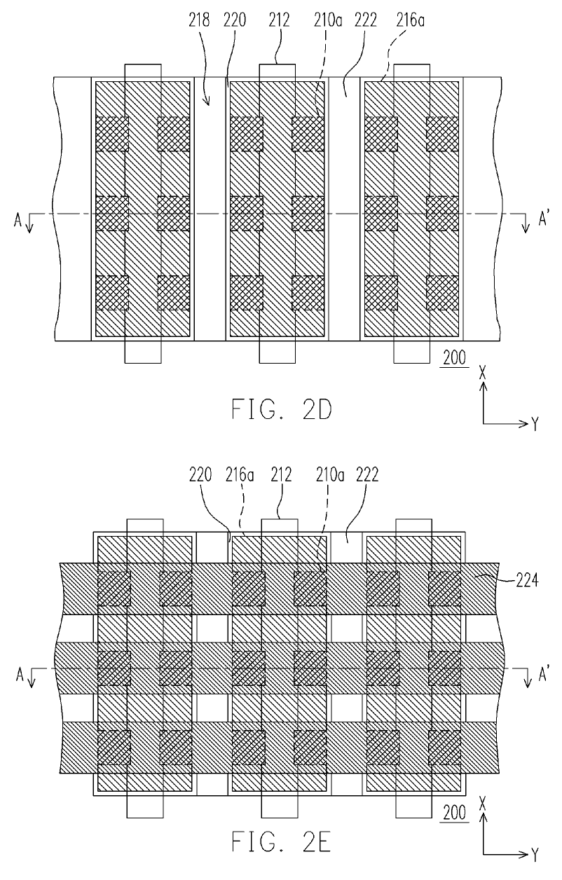

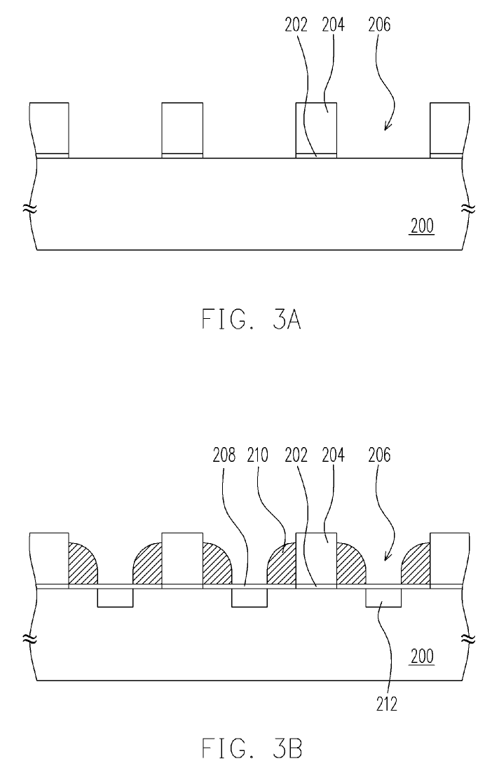

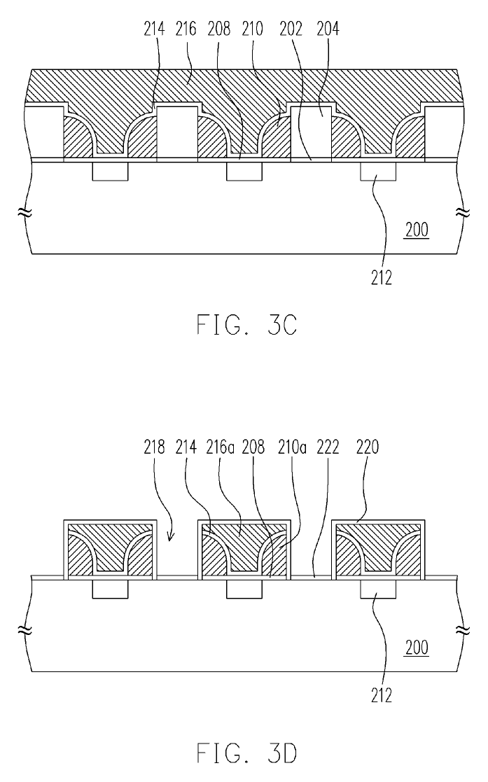

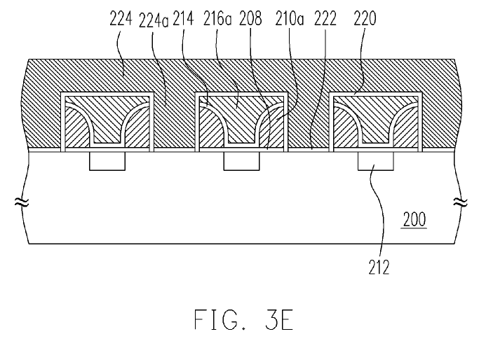

FIGS. 2A-2E are top views illustrating the process steps for forming a flash memory structure according to one preferred embodiment of the present invention. FIGS. 3A-3E are cross-sectional views illustrating the process steps for forming the flash memory structure of FIGS. 2A-2E along the line A-A′, according to the preferred embodiment of the present invention.

Referring to FIGS. 2A and 3A, a substrate 200, for example, a silicon substrate is provided. A pad layer 202 is formed on the substrate 200. The material of the pad layer 202 can be silicon oxide formed by thermal oxidation, for example. A mask layer 204 is formed over the substrate 200. The material of the mask layer 204 has an etching selectivity different from that of the subsequently formed floating gate or control gate. The material of the mask layer 204 is silicon nitride formed by chemical vapor deposition (CVD), for example. Later on, the mask layer 204 is patterned to form a plurality of trenches 206 that expose a portion of the pad layer 202. The trenches 206 in the mask layer 204 are in strip shapes, for example. A portion of the pad layer 202 that is exposed by the trenches 206 is removed by, for example, wet etching using hydrogen fluoride as the etchant. After removing a portion of the pad layer 202, a portion of the substrate 200 within the trenches 206 is exposed.

Referring to FIGS. 2B and 3B, a tunneling oxide layer 208 is formed on the exposed substrate 200 within the trenches 206. The material of the tunneling oxide layer is silicon oxide formed by thermal oxidation, for example.

Next, a plurality of conductive spacers 210 are formed on sidewalls of the trenches 206. The conductive spacers 210 are in strip shapes and the top surface of the conductive spacer 210 can be lower than the top surface of the mask layer 204, for example. The method for forming the conductive spacers 210, for example, includes forming a conductive material layer (not shown) over the substrate 200 and then etching back in a self-aligned way. The material of the conductive spacers 210 is doped polysilicon, for example, formed by either depositing an un-doped polysilicon layer by CVD and then implanting dopants or deposition by CVD with in-situ doping.

Afterwards, using the strips of conductive spacers 210 and the mask layer 204 as masks, ion implantation is performed to form a plurality of source/drain regions 212 (as buried bit-lines) in the substrate 200.

Referring to FIGS. 2C and 3C, using a photomask (not shown) with a pattern for defining the conductive spacers 210 to form a plurality of floating gates 210a. The floating gates 210a are in block shapes and arranged in arrays, for example. A first inter-gate dielectric layer 214 is formed over the substrate 200. The material of the first inter-gate dielectric layer 214 can be silicon oxide/silicon nitride/silicon oxide, or silicon oxide or silicon oxide/silicon nitride, for example. Taking the silicon oxide/silicon nitride/silicon oxide layer as an example, the first inter-gate dielectric layer 214 can be formed by forming a silicon oxide layer by thermal oxidation, a silicon nitride layer by CVD and then oxidizing a portion of the silicon nitride layer by using wet hydrogen/oxygen (H₂/O₂).

Then, a conductive layer 216 is formed over the substrate 200 to fill the trenches 206. The material of the conductive layer 216 is doped polysilicon, for example, formed by either depositing an un-doped polysilicon layer by CVD and then implanting dopants or deposition by CVD with in-situ doping.

Referring to FIGS. 2D and 3D, a portion of the conductive layer 216 is removed until the surface of the mask layer 204 is exposed, so that a plurality of control gates 216a is formed. The floating gates 210a within the same trench 206 share one control gate 216a. The method for removing a portion of the conductive layer 216 can be anisotropic etching or chemical mechanical polishing (CMP), for example.

Afterwards, the mask layer 204, a portion of the first inter-gate dielectric layer 214 and the pad layer 202 are removed to form a plurality of trenches 218 that expose the sidewalls of the control gates 216a and the sidewalls of the floating gates 210a and a portion of the substrate 200. The method for removing the mask layer 204, a portion of the first inter-gate dielectric layer 214 and the pad layer 202 can be wet etching or dry etching, for example. A second inter-gate dielectric 220 is formed on the top surface and sidewalls of the control gates 216a and on the sidewalls of the floating gates 210a, while a gate dielectric layer 222 is formed on the substrate 200 that is exposed by the trenches 218. The materials of the second inter-gate dielectric 220 and the gate dielectric layer 222 can be silicon oxide formed by thermal oxidation, for example. During the formation of the second inter-gate dielectric layer 220, sharp corners are often formed around the top portion of the floating gates 210a. Such sharp corner may generate higher electric field during erasure, thus enhancing the erasure efficiency for the flash memory.

Referring to FIGS. 2E and 3E, a plurality of word lines 224 are formed over the floating gates 210a. The word lines 224 are disposed above the floating gates 210a and fill up the trenches 218. The extension direction of the word lines 224 and the extension direction of the underlying source/drain regions 212 (buried bit-lines) are intersected. A portion of the word lines 224 that is filled into the trenches 218 and disposed between two adjacent floating gates 210a and two adjacent control gates 216a can function as the select gate 224a. The word lines 224 can be formed by forming a conductive material layer (not shown) over the substrate 200 and then patterning the conductive material layer by photolithography and etching. The following fabrication processes for the flash memory are well-known and will not be described further in details.

According to the preferred embodiment of this invention, during the formation of the floating gates 210a, the conductive spacers 210 are firstly formed in a self-aligned way and then patterned to form the floating gates 210a. The formed floating gates 210a are self-aligned with the mask layer 204 (and later the select gates 224a). Comparing with the prior art, at least one photolithography process is omitted so that fabrication processes are simplified and the production costs become lower, and the process window is increased by self-alignment.

Moreover, according to the preferred embodiment of this invention, the control gates 216a can be formed by depositing a conductive layer to fill the trenches 206 and removing the extra conductive layer until the mask layer is exposed by either etching back or CMP. During the formation of the control gates 216a, no lithography process is required, whereby the process window is loose and the production time and costs can be saved.

In addition, the floating gate 210a formed by the method of this invention has a curved top portion and a curved side (i.e. in a half-arc shape). Therefore, the overlapped area between the floating gate 210a and the control gate 216a becomes larger, when comparing with the prior art. As a result, the gate couple ratio between the floating gate 210a and the control gate 216a is increased and the operation speed and performance of the device are enhanced.

Besides, sharp corners formed on the top portion of the floating gate 210a (close to the word line 224) can generate higher electric field during erasing data, and electrons may rapidly enter the select gate 224a (word line 224) through the sharp corner, thus reducing the time required for erasing operation.

The present invention provides a flash memory structure, as shown in FIGS. 2E and 3E. The flash memory structure includes a substrate 200, a plurality of buried bit-lines (source/drain regions 212), a plurality of word lines 224, a plurality of select gates 224a, a plurality of floating gates 210a, a plurality of control gates 216a, a plurality of first inter-gate dielectric layers 214, a plurality of second inter-gate dielectric layers 220, a plurality of gate dielectric layers 222 and a plurality of tunneling dielectric layers 208.

The substrate 200 is, for example, a silicon substrate. The buried bit-lines (source/drain regions 212) are arranged in parallel to each other in the substrate 200, and extend in X direction, for example. The word lines 224 are arranged in parallel to each other above the substrate 200, and extend in Y direction, for example. The direction X crosses the direction Y. The select gates 224a are disposed below the word lines 224 and between, but not connected to the buried bit-lines (source/drain regions 212) by a separate distance. The floating gates 210a are arranged in arrays and disposed on the sidewalls of the select gates 224a. The floating gates 210a are adjacent to the buried bit-lines (source/drain regions 212). The top portion of the floating gate 210a adjacent to the select gate 216a has the sharp corner that is lower than the surface of the select gate 224a. The control gates 216a are disposed above the buried bit-lines (source/drain regions 212) and fill between two adjacent select gates 224a.

The first inter-gate dielectric layers 214 are disposed between the control gates 216a and the floating gates 210a and between the control gates 216a and the buried bit-lines (source/drain regions 212). The second inter-gate dielectric layers 220 are disposed between the word lines 224 and the control gates 216a and between the floating gates 210a and the select gates 224a. The gate dielectric layers 222 are disposed between the select gates 224a and the substrate 200. The tunneling dielectric layers 208 are disposed between the floating gates 210a and the substrate 200.

For the flash memory structure of this invention, top and side of the floating gate 210a form a curve shape (i.e. in a half-arc shape). Therefore, the overlapped area between the floating gate 210a and the control gate 216a becomes larger, when comparing with the prior art. As a result, the gate couple ratio between the floating gate 210a and the control gate 216a is increased and the operation speed and performance of the device are enhanced.

Besides, sharp corners on the top portion of the floating gate 210a (close to the word line 224) can generate higher electric field during information erasure, and electrons may rapidly enter the select gate 224a (word line 224) through the sharp corner, thus reducing the time required for erasing operation.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for fabricating a flash memory structure, comprising:
providing a substrate;
forming a mask layer on the substrate;
patterning the mask layer to form a plurality of first trenches;
forming a tunneling dielectric layer on a bottom surface of the first trenches;
forming plural strips of conductive spacers on sidewalls of the first trenches;
forming a plurality of source/drain regions in the substrate within the first trenches, using the conductive spacers as masks;
patterning the strips of conductive spacers to form a plurality of floating gates;
forming a first inter-gate dielectric layer over the substrate;
forming a plurality of control gates that fill up the first trenches;
removing the mask layer to form a plurality of second trenches;
forming a gate dielectric layer on a bottom surface of the second trenches and forming a second inter-gate dielectric layer covering the floating gate and the control gate; and
forming a plurality of word lines over the floating gates, wherein the word lines fill up the second trenches between the floating gates and an extension direction of the word line intersects with that of the source/drain region.

2. The method of claim 1, wherein the step of forming the plural strips of conductive spacers on sidewalls of the first trenches comprises:
forming a first conductive layer over the substrate; and
removing a portion of the first conductive layer by a self-aligned anisotropic etching process, so as to form the strips of conductive spacers.

3. The method of claim 1, wherein the step of forming a plurality of control gates that fill up the first trenches comprises:
forming a second conductive layer over the substrate; and
removing a portion of the second conductive layer outside the first trenches to form the control gates.

4. The method of claim 3, wherein a method of removing a portion of the second conductive layer outside the first trenches includes anisotropic etching or chemical mechanical polishing.

5. The method of claim 1, wherein a top surface of the strips of conductive spacer is lower than a surface of the mask layer.

6. The method of claim 1, wherein a material of the first inter-gate dielectric layer includes silicon oxide/silicon nitride/silicon oxide.

7. The method of claim 1, wherein a material of the second inter-gate dielectric layer includes silicon oxide.

8. The method of claim 1, wherein a material of the gate dielectric layer includes silicon oxide.

9. The method of claim 1, wherein a method for forming a gate dielectric layer on a bottom surface of the second trenches and forming a second inter-gate dielectric layer covering the floating gate and the control gate includes thermal oxidation.

10. The method of claim 1, wherein a material for forming the control gate and the floating gate includes doped polysilicon.

11. The method of claim 1, wherein a material of the mask layer has an etching selectivity different from that of a material of the floating gate and that of a material of the control gate.

12. The method of claim 11, wherein the material of the mask layer includes silicon nitride.

13. The method of claim 1, further comprising forming a pad layer on the substrate before forming the mask layer.

14. The method of claim 13, wherein a method for forming the pad layer includes thermal oxidation.

15. The method of claim 13, wherein in the step of patterning the mask layer, the method further comprises removing the pad layer exposed by the first trenches.

16. A flash memory structure, comprising
a substrate;
a plurality of buried bit-lines, disposed in the substrate, arranged parallel to each other and extended in a first direction;
a plurality of word lines, disposed over the substrate, arranged parallel to each other and extended in a second direction;
a plurality of select gates, disposed below the word lines and between the buried bit-lines;
a plurality of floating gates, disposed respectively on sidewalls of the select gates, wherein the other sides of the floating gates are adjacent to the buried bit-lines and top portions of the floating gates have sharp corners that are lower than a top surface of the select gates;
a plurality of control gates, disposed above the buried bit-lines and between two adjacent floating gates;
a plurality of first inter-gate dielectric layers, disposed between the control gates and the floating gates and between the control gates and the buried bit-lines;
a plurality of second inter-gate dielectric layers, disposed between the word lines and the control gates and between the floating gates and the select gates;
a plurality of gate dielectric layers disposed between the select gates and the substrate; and
a plurality of tunneling dielectric layers, disposed between the floating gates and the substrate.

17. The structure of claim 16, wherein the word lines and the select gates are integral.

18. The structure of claim 16, wherein a material of the first inter-gate dielectric layer includes silicon oxide/silicon nitride/silicon oxide.

19. The structure of claim 16, wherein a material of the second inter-gate dielectric layer, the gate dielectric layer and the tunneling dielectric layer includes silicon oxide.

20. The structure of claim 16, wherein a material for forming the floating gate and the control gate includes doped polysilicon.
